(19) United States
(12) Patent Application Publication
(10) Pub. No.: US 2014/0021433 A1
(43) Pub. Date: Jan. 23, 2014

(54) MICROELECTRONIC DEVICE WITH PROGRAMMABLE MEMORY

(71) Applicant: ALTIS Semiconductor, Paris (FR)

(72) Inventor: Faiz Dahmani, La Varenne-Saint Hilaire (FR)

(21) Appl. No.: 13/936,271

(22) Filed: Jul. 8, 2013

(30) Foreign Application Priority Data
Jul. 11, 2012 (FR) FR 12 56691

(51) Int. Cl. H01L 45/00

(52) U.S. Cl. CPC H01L 45/141; H01L 45/16
USPC 257/4; 438/382

(57) ABSTRACT

A microelectronic device with programmable memory is provided having at least: a first electrode (1) and a second electrode (9) having positioned between them a first layer of doped chalcogenide material (5) having an atomic concentration n1 of a doping metallic element d1. The device further has a second layer of doped chalcogenide material (8) positioned between the first electrode (1) and the second electrode (9), the second layer of doped chalcogenide material (8) having an atomic concentration n2 of a doping metallic element d2, the atomic concentration n2 being strictly less than the atomic concentration n1.

### RELATED APPLICATION

This application claims the benefit of priority from French Patent Application No. 12 56691, filed on Jul. 11, 2012, the entirety of which is incorporated by reference.

### BACKGROUND

1. Field of the Invention

The present invention relates to a microelectronic device with programmable memory, and also to a method of fabricating said device.

2. Description of Related Art

Microelectronic devices with programmable memory are typically, but not exclusively, programmable ion-conduction (metallization) cells constituting so-called “non-volatile” computer memories. Such programmable ion-conduction cells are well known as conductive-bridging random access memory (CBRAM) or as programmable metallization cells (PMCs).

This type of microelectronic structure (CBRAM or PMC) is well known to the person skilled in the art, and for example it is described in document U.S. Pat. No. 6,084,796.

A CBRAM (or PMC) typically comprises a vertical stack of layers formed on a substrate based on a semiconductor of the silicon type, having the following successive layers thereon: a so-called “bottom” electrode, a layer of a chalcogenide glass doped with silver (i.e. a solid electrolyte), and a so-called “top” electrode made of silver. The layer of a chalcogenide glass is thus interposed between the bottom electrode and the top electrode.

These electrodes are configured to cause a metallic dendrite to grow from the more negative one of these two electrodes towards the more positive one of these two electrodes through the layer of doped chalcogenide glass whenever an electric voltage is applied between said electrodes (i.e. an electrical conduction bridge is formed). By applying an opposite electric voltage between those two electrodes, the inverse phenomenon is obtained, i.e. the metallic dendrite disappears (i.e. the electrical conduction bridge disappears) from within the layer of doped chalcogenide glass.

Thus, when the electrical conduction bridge is created (a so-called “write” step), the logic state of the device may be represented by a “1”, or may correspond to a “ON” state, whereas when the electrical conduction bridge disappears, the logic state of the cell may be represented by a “0” or may correspond to the “OFF” state.

A first looked-for function in CBRAMs is to have a microelectronic structure that presents the highest possible electrical efficiency. The electrical efficiency of a memory structure may depend on the stoechiometry of the chalcogenide, or in other words on the atomic percentages of the various elements making up the chalcogenide. Said stoechiometry is an essential factor for obtaining good electrical performance in programmable ion-conduction cells.

A second looked-for function in CBRAMs is to have a microelectronic structure that presents a retention time (for retaining information in the memory) that is as long as possible, which may be achieved in particular by having a compact layer of a chalcogenide glass. Once the electrical conduction bridge has been formed by applying an electric voltage between the two electrodes, the retention time corresponds to the lifetime of the electrical conduction bridge when said voltage is no longer applied.

When an electric voltage is applied, the electrical conduction bridge forms at the base of the bottom electrode and grows towards the top electrode: this growth is referred to as longitudinal growth between the two electrodes.

Nevertheless, lateral growth also occurs, in particular close to the bottom electrode, from where the growth of the electrical conduction bridge begins. This lateral growth can contribute strongly to the conduction bridge being unstable, and even to it rupturing. One of the main causes of this lateral growth and/or of the conduction bridge rupturing is in particular the presence of a so-called “unlimited” source of metallic ions (i.e. the silver top electrode).

Mention may also be made of document US 2005/0250271, which describes a microelectronic device with programmable memory having at least a first electrode and a second electrode with a single layer of doped chalcogenide material positioned between them, this single layer possibly having zones of different doping, in particular. The method implemented in that type of structure is complex and does not guarantee reproducibility and stability for the electrical conduction bridge in an operational configuration of the microelectronic device.

### OBJECTS AND SUMMARY

The object of the present invention is to mitigate the drawbacks of the techniques of the prior art, in particular by proposing a microelectronic device with programmable memory that presents an electrical conduction bridge that is stable and reproducible in an operational configuration.

The present invention provides a microelectronic device with programmable memory (i.e. programmable memory microelectronic device) comprising at least: a first electrode and a second electrode having positioned between them a first layer of doped chalcogenide material having an atomic concentration n1 of a doping metallic element d1, the device being characterized in that it further comprises a second layer of doped chalcogenide material positioned between the first electrode and the second electrode, the second layer of doped chalcogenide material having an atomic concentration n2 of a doping metallic element d2, the atomic concentration n2 being strictly less than the atomic concentration n1, the atomic concentration n2 preferably being less than half the atomic concentration n1.

Surprisingly, it has been found that the second layer of doped chalcogenide material, a layer which is distinct from the first layer, makes it possible to obtain a microelectronic device with programmable memory that significantly limits or even avoids lateral growth of the electrical conduction bridge in an operational configuration of the device. As a result, retention time is significantly improved.

In the present invention, the term “layer of chalcogenide material” is used to mean a layer comprising a chalcogenide material, said chalcogenide material being defined below in the present description.

The doping metallic element d1 and the doping metallic element d2 may be identical or different. These doping metallic elements d1 and d2 are defined in the description below.

Concerning the concentrations n1 and n2 of the doping metallic elements, because of the different atomic concentrations n1 and n2 respectively in the first and second layers of doped chalcogenide material, the first layer of doped chalcogenide material can act as a so-called “active” electrode, thereby contributing to forming the electrical conduction bridge that is created between the two electrodes when an electric voltage is applied between those two electrodes. By extension, and in comparison with the above-mentioned prior art, this first layer of doped chalcogenide material performs substantially the same function as that performed by the silver top electrode in the prior art.

Consequently, the second layer of doped chalcogenide material can thus be the “memory” layer as such of a programmable ion-conduction cell, this “memory” layer being the programmable portion of the microelectronic device with programmable memory.

More particularly, the doping element d1 of the doping element d2 respectively in the first layer and in the second layer are distributed in substantially uniform and homogenous manner throughout the thickness of each of said layers. In contrast to a gradient type concentration distribution in a single layer, this homogenous distribution in each of the two layers of the invention has the advantage of guaranteeing that the electrical conduction bridge is reproducible and stable in an operational configuration of the device of the invention.

In more particularly preferred manner, the atomic concentration n2 of d2 may lie in the range 2% to 10% and the atomic concentration n1 of d1 may lie in the range 10% to 40%, taking aocount in particular of the solubility point of the doping metallic element, which itself depends on the stoechiometry of the chalcogenide used.

Preferably, the first layer of doped chalcogenide material may be an amorphous layer and/or the second layer of doped chalcogenide material may be an amorphous layer.

In order to guarantee a structure that is amorphous throughout the method of fabricating the microelectronic device with programmable memory, the glass transition temperature Tg of the layer of doped chalcogenide material in question is preferably higher than the fabrication temperatures used in the steps of fabricating said device, and in particular in the steps necessary for making the device usable as a CBRAM (including the steps of installing active components such as transistors, . . . , etc.).

The glass transition temperatures of the first and second layers of doped chalcogenide material can be measured easily by modulated differential scanning calorimetry (MDSC) with temperature rising at a rate of 3 degrees Celsius per minute° (C/min) and with modulation at a speed of 1 degree Celsius per hundred second (° C./100 s).

It is well known than the presence of a doping metallic element in a chalcogenide material reduces the glass transition temperature of said chalcogenide material. As a result, the quantity of the doping metallic element within the first layer of doped chalcogenide material and/or the second layer of doped chalcogenide material is preferably determined so as to preserve the amorphous properties of those layers once they have been doped.

The first and second electrodes of the invention may preferably be metallic electrodes, made and deposited by techniques that are well known to the person skilled in the art. They correspond respectively to an anode and to a cathode, or vice versa.

Preferably, the first electrode may be an inert electrode and/or the second electrode may be an inert electrode.

The term “inert electrode” is used to mean an electrode that does not contribute to forming the electrical conduction bridge. In other words, the material of the electrode is different from that constituting the metallic element doping the layers of doped chalcogenide material.

The first electrode and/or the second electrode may typically be metallic electrodes, and in particular electrodes made of metallic elements that are different from the doping metallic elements d1 and d2.

By way of example, the first electrode and/or the second electrode may be made of a material that may be selected equally well from nickel, a nickel alloy, tungsten, a tungsten alloy, titanium, titanium nitride, tantalum, and tantalum nitride, or a mixture thereof.

The layers of doped chalcogenide material of the invention are typically for use in forming the solid electrolyte of the microelectronic device with programmable memory. Thus, the layers of doped chalcogenide material are conventionally placed between the first and second electrodes so as to be capable of forming electrical conduction bridges when a voltage is applied between those two electrodes. Consequently, the layers of chalcogenide are preferably in physical contact with both electrodes.

That said, if an intermediate layer is positioned between an electrode and one of the layers of chalcogenide material, it is essential for the layer of chalcogenide to be in electrical contact with said electrode, e.g. via electrically conductive materials enabling the layer of chalcogenide material to be electrically connected with said electrode.

In a particular embodiment, the second layer of doped chalcogenide material may be positioned between the first layer of doped chalcogenide material and the second electrode.

The first layer of doped chalcogenide material may be in direct physical contact with the second layer of doped chalcogenide material.

The first layer of doped chalcogenide material may be in direct physical contact with the first electrode.

The second layer of doped chalcogenide material may be in direct physical contact with the second electrode.

In a particularly preferred embodiment, the first electrode may be in direct physical contact with the first layer of doped chalcogenide material, the first layer of doped chalcogenide material may be in direct physical contact with the second layer of doped chalcogenide material, and the second layer of doped chalcogenide material may be in direct physical contact with the second electrode.

In a particular embodiment, the first layer of doped chalcogenide material has thickness that is greater than or equal so the thickness of the second layer of doped chalcogenide material. By way of example, the first layer of doped chalcogenide material may have thickness lying in the range 5 nanometers (nm) to 100 nm; and the second layer of doped chalcogenide may have thickness lying in the range 2 nm to 30 nm.

As an indication, the first and second electrodes may have thickness lying respectively in the range 5 nm to 10 nm and in the range 10 nm to 20 nm.

In a preferred embodiment, the microelectronic device with programmable memory of the invention is a programmable ion-conduction cell (CBRAM or PMC), or in other words an ion-conduction programmable memory microelectronic device.

The invention also provides a method of fabricating the microelectronic device with programmable memory, as defined in the present invention, the method comprising the following steps:

A) forming on the first electrode a first layer of doped chalcogenide material having an atomic concentration n1 of a doping metallic element d;

B) forming on the first layer of doped chalcogenide material a second layer of doped chalcogenide material having an atomic concentration n2 of a doping metallic element d2, the atomic concentration n2 being strictly less than the atomic concentration n1; and

C) depositing a second electrode on the second layer of doped chalcogenide material in order to form said microelectronic device.

In a first particular implementation, method of fabricating the microelectronic device with programmable memory, as defined in the present invention, may comprise the following steps:

i) depositing a first layer of chalcogenide material on the first electrode;

ii) depositing a first doping metallic layer on the first, layer of chalcogenide material;

iii) dissolving the first doping metallic layer into the first layer of chalcogenide material in order to dope the first layer of chalcogenide material and form a first layer of doped chalcogenide material having an atomic concentration n1 of a doping metallic element d1;

iv) depositing a second layer of chalcogenide material on the first layer of doped chalcogenide material;

v) depositing a second doping metallic layer on the second layer of chalcogenide material;

vi) dissolving the second doping metallic layer into the second layer of chalcogenide material in order to dope the second layer of chalcogenide material and form a second layer of doped chalcogenide material having an atomic concentration n2 of a doping metallic element d2, the atomic concentration n2 being strictly less than the atomic concentration n1; and

vii) depositing a second electrode on the second layer of doped chalcogenide material in order to form said microelectronic device.

Consequently, steps i, ii, and iii come within step A, steps iv, v, and vi come within step B, and step vii is step C.

The chalcogenide material of the first layer (step i) and the chalcogenide material of the second layer (step iv) are materials that may be identical or different, and they are materials that are for doping with at least one doping metallic element, which elements may be identical or different. Thus, these chalcogenide materials are preferably so-called “non-doped” materials, and more particularly materials that do not include any dissolved or diffused doping metallic element within the layer of chalcogenide material in question.

The chalcogenide materials of the first layer (step i) and of the second layer (step iv) are preferably amorphous materials. The first layer of chalcogenide (step i) and/or the second layer of chalcogenide (step iv) are more particularly chalcogenide glasses.

A chalcogenide is conventionally at least one chalcogen ion and at least one electropositive element.

The chalcogens, constituting the chalcogen ions, are to be found in group 16 of the periodic table of the elements, and those that are preferably used in the invention are sulfur (S), selenium (Se), and tellurium (Te).

The electropositive element constituting the chalcogenide may in particular be an element from group 14 or group 15 of the periodic table of the elements, and is preferably germanium (Ge) or arsenic (As).

As examples of chalcogenides, mention may be made of germanium selenide GeₓSe₁₀₀₋ₓ, germanium sulfide GeₓS₁₀₀₋ₓ, or arsenic sulfide AsₓS₁₀₀₋ₓ, where x is an integer, in particular lying in the range 1 to 99, and preferably in the range 18 to 50.

The prefer chalcogenide is germanium sulfide GeₓS₁₀₀₋ₓ in particular with 33≦x≦44, and in more particularly preferred manner with x=33.

The layer of chalcogenide material may typically be deposited by a method well, known to the person skilled in the art such as cathode sputtering.

The first electrode (step i) and the second electrode (step vii) are defined above and may be deposited by techniques well known to the person skilled in the art.

In the present invention, the first electrode may be deposited on the substrate in conventional manner. The term “substrate” is used to mean any type of structure, such as in particular semiconductor substrates, that may conventionally be based on silicon and/or on quartz. By way of example, the semiconductor substrate may be selected from substrates of silicon, of silicon oxide, and of quartz.

By way of example, the semiconductor substrate may comprise semiconductors of the silicon on insulator (SOI) type, of the silicon on sapphire (SOS) type, doped or non-doped semiconductors, or layers of silicon grown epitaxially on a semiconductor base. Steps of the method may be used for forming regions or junctions in or above the semiconductor base.

The substrate is not necessarily a semiconductor, but may be any type of support structure suitable for supporting an integrated circuit. For example, the substrate may be made of ceramic or based on polymer.

By way of example, the substrate may have thickness lying in the range 150 micrometers (μm) to 400 μm, and possibly up to as much as 800 μm.

The first doping metallic layer that is deposited in step ii, and the second doping metallic layer that is deposited in step v, may be layers that are identical or different.

The first and second doping metallic layers are typically ionizable metallic layers for doping respectively the first layer of chalcogenide material of step i and the second layer of chalcogenide material of step iv.

More particularly, the first doping metallic layer comprises at least one doping metallic element d1 and the second doping metallic layer comprises at least one doping metallic element d2, these doping metallic elements being for doping the layers of chalcogenide material.

It is preferable to use the same doping metallic elements d1 and d2 for doping the first layer of chalcogenide material (step i) and the second layer of chalcogenide material (step iv). As a result, the doping metallic element d1 may in particular be identical to the doping metallic element d1.

The doping metallic element of the first doping metallic layer and/or of the second doping metallic layer may be selected equally well from silver (Ag), an alloy of silver, copper (Cu), an alloy of copper, zinc (Zn), and an alloy of zinc, or a mixture thereof, with the particularly preferred element being silver or an alloy of silver.

In a particular embodiment, the first doping metallic layer presents thickness that is greater than or equal to the thickness of the second doping metallic layer. By way of example, the first doping metallic layer may have thickness lying in the range 3 nm to 10 nm; and the second doping metallic layer have thickness lying in the range 1 nm to 2 nm.

In a particular implementation of step iii, the dissolution of the first doping metallic layer is total.

In a particular implementation of step vi, the dissolution of the second doping metallic layer is total.

The term “total dissolution” is used to mean total dissolution or diffusion of the doping metallic elements (from the doping metallic layer) through the layer of chalcogenide material, such that there remains substantially no doping metallic layer on the surface of the layer of chalcogenide material after the dissolution step in question.

The person skilled in the art can easily verify that the layer of chalcogenide material, once doped, is substantially free from any residual doping metallic layer on its surface by using techniques that are well known, e.g. with the help of a transmission electron microscope (TEM). TEM measurements are conventionally performed at ambient temperature (about 25° C.), but they may also be performed at a temperature of less than 25° C., and more particularly at a temperature of less than 0° C. when the doping metallic layer has a high degree of ion mobility, in particular a high degree of ion mobility at ambient temperature.

It may in particular be considered that each doping metallic layer is dissolved (i.e. diffused) totally (i.e. the residual doping metallic layer after dissolution is substantially non-existent) when it has a thickness of no more than 0.5 nm, and preferably of no more than 0.2 nm. In other words, after step iii and/or after step vi, the doping metallic layer in question has a thickness that is in particular no greater than 0.5 nm and preferably no greater than 0.2 nm.

Consequently, it is preferable for the doping metallic layer deposited in step ii and/or the doping metallic layer deposited in step v to present thickness that is sufficiently small for the doping metallic elements to be capable of being diffused totally during the respective dissolution steps iii and vi.

Typically, the dissolution of the first doping metallic layer may be performed by irradiation with ultraviolet irradiation and/or by heat treatment.

Likewise, the dissolution of the second doping metallic layer may be performed by irradiation with ultraviolet radiation and/or by heat treatment.

Both irradiation with ultraviolet irradiation and heat treatment for dissolving the doping metallic layer (i.e. the ionizable metallic layer) are methods that are well known to the person skilled in the art.

When the first and second doping metallic layers have been dissolved by irradiation with ultraviolet radiation, the density of the irradiation, typically expressed in milliwatts per square centimeter (mW/cm²) that is used in step iii is preferably greater than the density of the irradiation that it used in step vi.

When the first and second doping metallic layers are dissolved by heat treatment, the duration of the heat treatment used in step iii is preferably longer than the duration of the heat treatment used in step vi, for a heat treatment temperature that is the same in step iii and in step vi.

In a second particular implementation, step A and/or step B of said method of fabricating the microelectronic device with programmable memory, may be performed by simultaneously sputtering a chalcogenide material (i.e. a “non-doped” chalcogenide material) and a doping metallic element, the chalcogenide material and the doping metallic element being as defined in the present invention.

In a third particular implementation, the first and second implementations may be combined.

For example, step A may be performed using the second implementation (i.e. simultaneous sputtering), while step B may be implemented in accordance with the first implementation (i.e. step B=steps iv+v+vi); or else step A may be implemented in accordance with the first implementation (i.e. step A=steps i+ii+iii), while step B is implemented in accordance with the second implementation (i.e. simultaneous sputtering).

### BRIEF DESCRIPTION OF THE DRAWINGS

Other characteristics and advantages of the present invention appear in the light of the following examples given with reference to the annotated figures, said examples and figures being given by way of non-limiting illustration.

FIG. 1 shows a succession of steps in the fabrication of a microelectronic device of the invention.

FIG. 2 shows the microelectronic obtained by the method as shown in FIG. 1.

### DETAILED DESCRIPTION

For reasons of clarity, elements that are the same are given references that are identical. Likewise, only elements that are essential for understanding the invention are shown and then only diagrammatically, and without necessarily being to scale.

### EXAMPLES

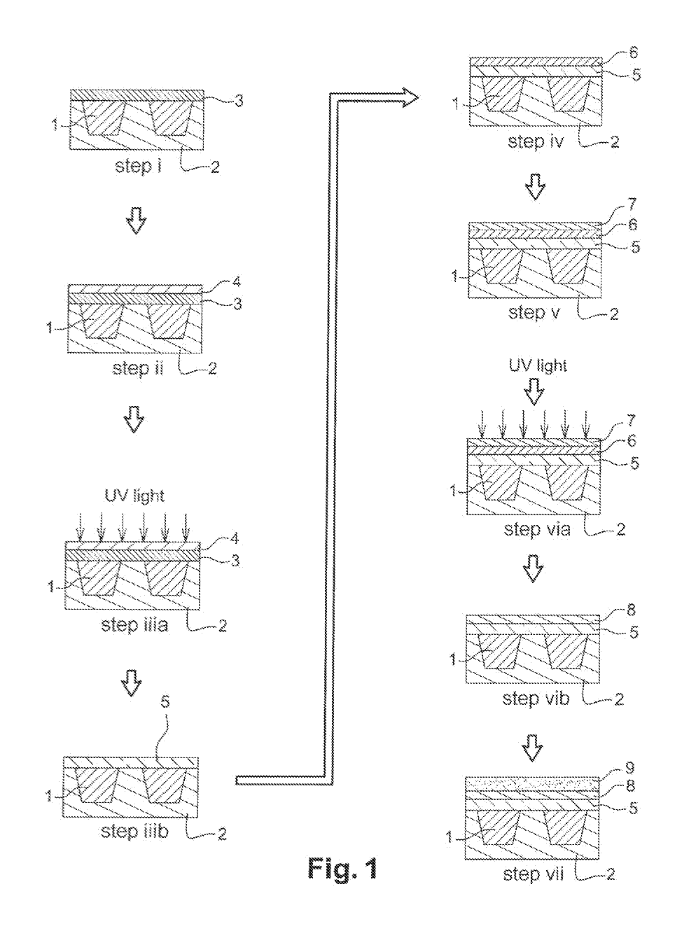

FIG. 1 shows a succession of steps for fabricating a microelectronic device in accordance with the invention.

Firstly, at the surface of at least one first (or “bottom”) electrode 1 that is inert, and in particular that is incorporated in an electrically insulating layer 2, there is deposited (step i) a first layer of non-doped chalcogenide material 3 of the GeS₂ type that is to be doped by a metallic doping element. The deposition technique conventionally used for depositing this first layer of chalcogenide material may be cathode sputtering. This first layer of chalcogenide material 3 may have a thickness of about 10 nm.

Thereafter, a first doping metallic layer 4 of the silver layer type is deposited (step ii) on the first layer of chalcogenide material 3. The deposition technique conventionally used may be cathode sputtering. This first layer of silver 4 may have thickness of about 1 mm to 3 mm.

The first layer of silver 4 is completely photo-dissolved (step iii) into the first layer of chalcogenide material 3 by irradiating the first layer of silver 4 with ultraviolet radiation (see step iiia). The operating conditions for the photo-dissolution are as follows: 50 mW/cm² to 80 mW/cm² for 10 min. A first layer of doped chalcogenide material 5 is thus obtained (see step iiib) having an atomic concentration n1 of silver that is about 26% atomic.

Thereafter, a second layer of non-doped chalcogenide material 6 of GeS₂ type is deposited (step iv) in order to be doped with a metallic doping element. The deposition technique conventionally used is the same as that mentioned for the first layer of chalcogenide material 3. This second layer of chalcogenide material 6 may have thickness of about 5 nm.

Thereafter, a second doping metallic layer 7 of the silver layer type is deposited. (step v) on the second layer of chalcogenide material 6. The deposition technique conventionally used is the sane as that mentioned above for the first doping metallic layer 4 This second layer of silver 7 may have thickness that is less than or equal to 1 nm.

The second layer of silver 7 is complete photo-dissolved (step vi) in the second layer of chalcogenide material 6 by irradiating the second layer of silver 7 with ultraviolet radiation (see step via). The operating conditions for the photo-dissolution are as follows: 20 mW/cm² to 50 mW/cm² for 1 min to 3 min. This obtains a second layer of doped chalcogenide material 8 (see step vib) having an atomic concentration n2 of silver of about 10% atomic.

Finally, an inert second electrode 9 (i.e. a “top” electrode) is deposited (step vii) on the second layer of doped chalcogenide 3 in order to form a microelectronic device of the invention.

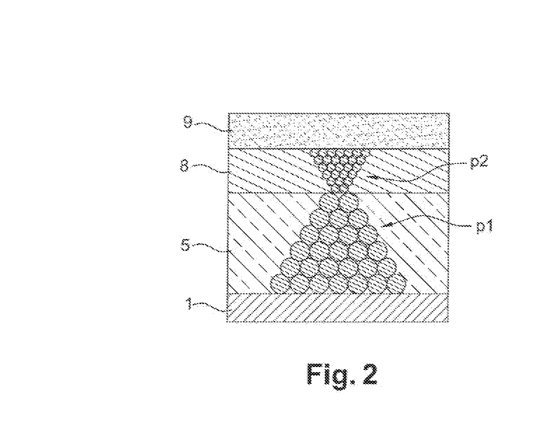

FIG. 2 shows the microelectronic device obtained by the method as shown in FIG. 1.

Thus, the microelectronic device has two inert electrodes 1 and 9 between which there are positioned the first layer of doped chalcogenide material 5 and the second layer of doped chalcogenide material 8.

In this embodiment, the first layer of doped chalcogenide material 5 is in direct physical contact with the first electrode 1 and with the second layer of doped chalcogenide material 8, and the second layer of doped chalcogenide material 8 is also in direct physical contact with the second electrode 9.

When an electric voltage is applied to the terminals of the first and second electrodes, a silver electrical conduction bridge forms between said electrodes within the first and second layers of doped chalcogenide material 5, 8. More particularly, a first electrical conduction bridge p1 forms within the first layer of doped chalcogenide material 5, and a second electrical conduction bridge p2 forms within the second layer of doped chalcogenide material 8, as shown diagrammatically in FIG. 2.

Since the atomic concentration n1 of the doping element (e.g. silver ions) d1 in the first layer of doped chalcogenide material 5 is greater than the atomic concentration n2 of the doping element (e.g. silver ions) d2 in the second layer of doped chalcogenide material 8, the first layer of doped chalcogenide material 5 may act as a so-called “active” electrode thus contributing to forming the electrical conduction bridge p2 via the electrical conduction bridge p1. In comparison with the prior art, this first layer of doped chalcogenide material 5 acts in substantially the same way as the silver top layer of the prior art.

Consequently, the electrical conduction bridge p2 formed within the second layer of doped chalcogenide material 8 then acts as a “memory” layer as such of a programmable ion-conduction cell. This “memory” layer is thus the programmable portion of the microelectronic device with programmable memory. The electrical conduction bridge p1 formed within the first layer of doped chalcogenide material 5 acts as a limited source of metallic ions, unlike the unlimited source of metallic ions in the prior art (i.e. top silver electrode).

1. An ion-conduction programmable memory microelectronic device comprising at least:
a first electrode and a second electrode having positioned between them a first layer of doped chalcogenide material having an atomic concentration n1 of a doping metallic element d1,
wherein a second layer of doped chalcogenide material is positioned between the first electrode and the second electrode, the second layer of doped chalcogenide material having an atomic concentration n2 of a doping metallic element d2, the atomic concentration n2 being strictly less than the atomic concentration n1.

2. A device according to claim 1, wherein the first layer of doped chalcogenide material is an amorphous layer.

3. A device according to claim 1, wherein the second layer of doped chalcogenide material is an amorphous layer.

4. A device according to claim 1, wherein the first electrode is an inert electrode.

5. A device according to claim 1, wherein the second electrode is an inert electrode.

6. A device according to claim 1, wherein the second layer of doped chalcogenide material is positioned between the first layer of doped chalcogenide material and the second electrode.

7. A device according to claim 1, wherein the first layer of doped chalcogenide material is in direct physical contact with the second layer of doped chalcogenide material.

8. A device according to claim 1, wherein the first layer of doped chalcogenide material is in direct physical contact with the first electrode.

9. A device according to claim 1, wherein the second layer of doped chalcogenide material is in direct physical contact with the second electrode.

10. A device according to claim 1, wherein the first electrode is in direct physical contact with the first layer of doped chalcogenide material, the first layer of doped chalcogenide material is in direct physical contact with the second layer of doped chalcogenide material, and the second layer of doped chalcogenide material is in direct physical contact with the second electrode.

11. A device according to claim 1, wherein the atomic concentration n2 is less than half the atomic concentration n1.

12. A device according to claim 1, wherein said device is a programmable ion-conduction cell (CBRAM or PMC).

13. A method of fabricating a microelectronic device according claim 1, the method comprising the steps of
A) forming on the first electrode a first layer of doped chalcogenide material having an atomic concentration n1 of a doping metallic element d1;
B) forming on the first layer of doped chalcogenide material a second layer of doped chalcogenide material having an atomic concentration n2 of a doping metallic element d2, the atomic concentration n2 being strictly less than the atomic concentration n1: and
C) depositing a second electrode on the second layer of doped chalcogenide material in order to form said microelectronic device.

14. A method according to claim 13, comprising the following steps:
i) depositing a first layer of chalcogenide material on the first electrode;
ii) depositing a first doping metallic layer on the first layer of chalcogenide material;
iii) dissolving the first doping metallic layer into the first layer of chalcogenide material in order to dope the first layer of chalcogenide material and form a first layer of doped chalcogenide material having an atomic concentration n1 of a doping metallic element d1;
iv) depositing a second layer of chalcogenide material on the first layer of doped chalcogenide material;
v) depositing a second doping metallic layer on the second layer of chalcogenide material;
vi) dissolving the second doping metallic layer into the second layer of chalcogenide material in order to dope the second layer of chalcogenide material and form a second layer of doped chalcogenide material having an atomic concentration n2 of a doping metallic element d2, the atomic concentration n2 being strictly less than the atomic concentration n1; and
vii) depositing a second electrode on the second layer of doped chalcogenide material in order to form said microelectronic device.

15. A method according to claim 14, wherein the dissolution of the first doping metallic layer is total.

16. A method according to claim 14, wherein the dissolution of the second doping metallic layer is total.

17. A method according to claim 14, wherein the dissolution of the first doping metallic layer is performed by irradiation with ultraviolet irradiation and/or by heat treatment.

18. A method according to claim 14, wherein the dissolution of the second doping metallic layer is performed by irradiation with ultraviolet, radiation and/or by heat treatment.
